(19) United States
(12) Patent Application Publication
(10) Pub. No.: US 2021/0105908 A1
(43) Pub. Date: Apr. 8, 2021

(54) CABLE MANAGEMENT ARM RETAINER

(71) Applicant: Hewlett Packard Enterprise Development LP, Houston, TX (US)

(72) Inventors: Daniel W. TOWER, Houston, TX (US); Kevin BOLD, Houston, TX (US)

(21) Appl. No.: 16/596,069

(22) Filed: Oct. 8, 2019

(51) Int. Cl. H05K 7/14

(52) U.S. Cl. CPC H05K 7/1491; H05K 7/1489

(57) ABSTRACT

A cable management arm retainer, comprising: an attachment bracket to pivotally connect to a support of a cable management arm and to connect to a rail kit connector; the rail kit connector including a first end, the first end to connect to first connector of a rail kit, and a second end, the second end opposite the first end and including a latch, wherein when the latch is actuated, the rail kit connector is allowed to change orientation in relation to the attachment bracket.

### BACKGROUND

Cable management arm designs do not include a support. In other words, when a computing device is extended or pulled from a rack, the cable management arm is not physically supported, other than at the point where the cable management arm attaches to a rail kit. Some computing device designs may utilize longer and heavier cables, in part due to the extra length of the computing device design and the extra distance that the computing device may be extended from a rack. The additional weight and length of the cables is too much for a cable management arm without additional support.

### BRIEF DESCRIPTION OF THE DRAWINGS

Non-limiting examples of the present disclosure are described in the following description, read with reference to the figures attached hereto and do not limit the scope of the claims. In the figures, identical and similar structures, elements or parts thereof that appear in more than one figure are generally labeled with the same or similar references in the figures in which they appear. Dimensions of components and features illustrated in the figures are chosen primarily for convenience and clarity of presentation and are not necessarily to scale. Referring to the attached figures:

FIG. 1A is a block diagram of a cable management arm, according to an example;

FIG. 1B is a block diagram of a cable management arm retainer, according to an example;

FIG. 2 is a schematic view of a cable management arm attached to a computing device, according to an example;

FIG. 3 is a close-up schematic view of a cable management arm attached to a computing device, according to an example;

FIG. 4 is a top-down schematic view of a cable management arm attached to a computing device, according to an example;

FIG. 5 is a schematic view of a cable management arm, in an extended position, attached to a computing device, according to an example;

FIG. 6 is a top-down schematic view of a cable management arm, in an extended position, attached to a computing device, according to an example;

FIG. 7 is a schematic view of the connector, according to an example;

FIG. 8 is a schematic view of two computing devices, one retracted and one extended, in a rack, each with a cable management arm, according to an example;

FIG. 9 is a method of attaching the cable management arm to a computing device, according to an example;

FIG. 10 is a close-up schematic view of cable management arm retainer, according to an example;

FIG. 11 is another close-up view of the cable management arm retainer, according to an example;

FIG. 12 is a close-up view of the rear of the cable management arm retainer, according to an example;

FIG. 13 is a close-up view of another cable management arm retainer, according to an example; and

FIG. 14 is a top-do close-up view of the other cable management arm retainer.

### DETAILED DESCRIPTION

In the following detailed description, reference is made to the accompanying drawings which form a part hereof, and in which is depicted by way of illustration specific examples in which the present disclosure may be practiced. It is to be understood that other examples may be utilized and structural or logical changes may be made without departing from the scope of the present disclosure.

Computing devices, particularly servers, may be added to or installed in a rack. A rack may be a structure for housing multiple computing devices. Generally, a rack may consist of four posts or columns with mounting holes or apertures to facilitate the addition or mounting of computing devices. A rail kit may attach to a computing device and to a rack, thus allowing a computing device to be mounted to the rack. Further, the rail kit may allow the computing device to be slid in and out of the rack while remaining mounted to the rack, thus providing access to a user for a portion of the computing device. The rail kit may be formed to support a certain weight, based on past models of computing devices. A cable management arm may refer to a support structure bested at the rear of a computing device. In an example, the cable management arm may attach to one of two rail kits attached to the computing device. The cable management arm may support the cables connected to a computing device as a computing device is pulled forward, pushed inward, in an extended position, and in a retracted position.

Cable management arm designs do not include a support. In other words, when a computing device is extended or pulled from a rack, the cable management arm is not physically supported, other than at the point where the cable management arm attaches to a rail kit. Some computing device designs may utilize longer and heavier cables, in part due to the extra length of the computing device design and the extra distance that the computing device may be extended from a rack. The additional weight and length of the cables is too much for a cable management arm without additional support.

Based on the issues described above, a support may be added underneath the cable management arm to add support. In an example, the support may be a rail kit or some other similar friction slide component, ball bearing component, other type of slide components, or some combination thereof. In an example, a rail kit (e.g., a friction slide support) for the cable management arm may be attached (for example, pivotally connected) to one side of a cable management arm retainer. The cable management arm retainer may be connected to the rail kit of the computing device (for example, the opposite rail kit of the computing device which the cable management arm may attach to). The rail kit for the cable management arm may connect to the cable management arm via a pin connected through a connector of the cable management arm to a slide of the rail kit for the cable management arm. In another example, the support for the cable management arm may connect to the same rail kit of the computing device as the cable management arm attaches to.

Examples described herein, include a cable management arm comprising a first cable management arm to connect to a first connector of a first rail kit of a computing device and a second cable management arm to connect to a second connector of the first rail kit of the computing device. The cable management arm may also comprise a connector to pivotally attach to the first cable management arm and the second cable management arm. The cable management arm may also comprise a rail kit. The rail kit may connect to a second rail kit of the computing device via a cable management arm retainer. The cable management arm retainer may include an attachment bracket to pivotally connect to the rail kit (in other words, the support for the cable management arm) and to connect to a rail kit connector. As the computing device is pulled from a rack and the cable management arm extends the rail kit (e.g., the support for the cable management arm) may pivot about the attachment bracket. The rail kit may comprise an inner slide and the inner slide may pivotally connect to the cable management arm retainer. The rail kit may comprise an outer slide and the outer slide may be slidably connected to the inner slide. The rail kit may also comprise a short slide, slidably connected to the outer slide, to allow for a maximum range of motion. The cable management arm may allow for the computing device to be extended further from a rack than a standard cable management arm (for example, a cable management arm without a support or rail kit) may allow.

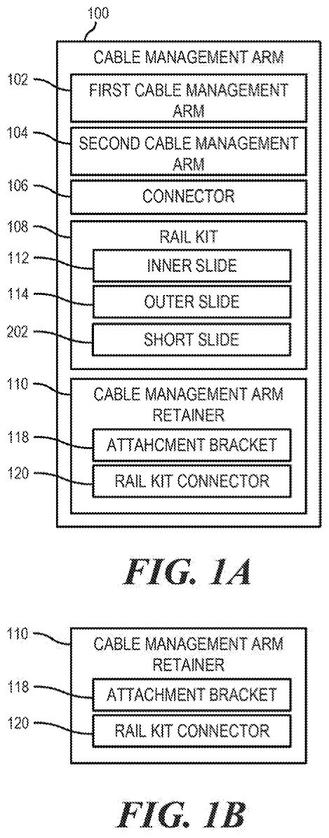

FIG. 1A is a block diagram of a cable management arm 100. The cable management arm 100 may comprise a first cable management arm 102 to connect to a first connector of a first rail kit of a computing device and a second cable management arm 104 to connect to a second connector of the first rail kit of the computing device. The cable management arm 100 may also comprise a connector 106 to pivotally attach to the first cable management arm 102 and the second cable management arm 104. The cable management arm 100 may also comprise a rail kit 108. The rail kit 108 may comprise an inner slide 112. The rail kit 108 may comprise an outer slide 114 and the outer slide 114 may be slidably connected to the inner slide 112. The rail kit 108 may comprise a short slide 202 slidably connected to the outer slide 114 and connected to the connector 106. The rail kit 108 may pivotally attach to the connector 106 of the cable management arm 100 via a pin or other fastener. The cable management arm 100 may also comprise a cable management arm retainer 110. The cable management arm retainer 110 may include an attachment bracket 118. The attachment bracket 118 may pivotally attach or connect to the inner slide 112 and may connect to a rail kit connector 120 of the cable management arm retainer 110. The rail kit connector 120 may include a first end to connect to a first connector of a second rail kit. The rail kit connector 120 may include a second end, opposite the first end, including a latch. When the latch is actuated, the rail kit connector 120 may change orientation in relation to the attachment bracket 118.

As used herein, a “computing device” may be a storage array, storage device, storage enclosure, server, blade server, desktop or laptop computer, computer cluster, node, partition, or any other device or equipment including a controller, a processing resource, or the like. In examples described herein, a “processing resource” may include, for example, one processor or multiple processors included in a single computing device or distributed across multiple computing devices. As used herein, a “processor” may be at least one of a central processing unit (CPU). a semiconductor-based microprocessor, a graphics processing unit (GPU), a field-programmable gate array (FPGA) to retrieve and execute instructions, other electronic circuitry suitable for the retrieval and execution instructions stored on a machine-readable storage medium, or a combination thereof.

As used herein, “rack unit” or “U” may refer to the unit of measurement to define the height of a rack frame and the height of the equipment rack frame (such as, computing devices). Each rack unit may be equivalent to 44.50 millimeters or 1.75 inches. For example, a computing device, such as a rack server, may have a height of 2 U or 2 rack units (in other words, 89 millimeters or 3.5 inches).

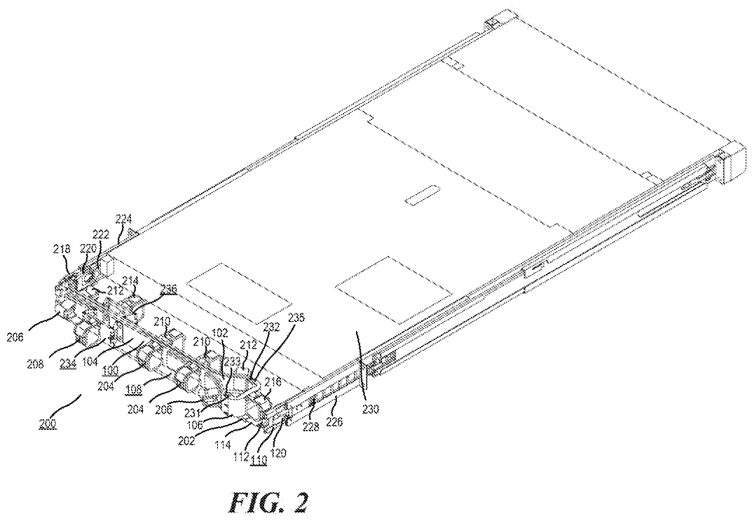

As used herein, “forward” refers to an orientation that is aligned with a horizontal vector pointing from a rear of the bracket assembly toward a front of the bracket assembly, while “rearward” refers to an orientation that is aligned with a horizontal vector pointing from a front of the bracket assembly toward a rear of the bracket assembly. In FIGS. 2-8 and 10-14, “forward” is aligned with the +y\hat{ }direction, while “rearward” is aligned with the −y\hat{ }direction. When one of the example rail kits is installed in a device rack, the “forward” orientation may be aligned with a vector extending from a rear column of the device rack to a front column of the device rack, and vice-versa for the “rearward” orientation. Forward movement or extension is movement or extension in a forward oriented direction, whereas rearward movement extension is movement or extension in a rearward oriented direction.

As used herein, “inward” refers to an orientation that is aligned with a vector that would point from the rail kit toward the electronic device if the electronic device were mounted to the rail kit. As used herein and in the appended claims, “outward” refers to an orientation that is the opposite of the “inward” orientation (i.e., an orientation that is aligned with a vector that would point away from the electronic device if the electronic device were mounted to the rail kit). “Inward” and “outward” for one rail kit will not necessarily be identical to “inward” and “outward” for another rail kit, since the different rail kits may be oriented differently from one another. For example, when a pair of rail kits is installed in a device rack, they may be facing each other, and thus “inward” for one of the rail kits may be pointing in an opposite direction as “inward” for the other one of the rail kits. For example, in FIGS. 2-8 and 10-14, “inward” is aligned with the +x\hat{ }direction for the left-side rail kit 10L, and with the −x\hat{ }direction for the right-side rail kit 10R. Similarly, “outward” is aligned with the −x\hat{ }direction for the left-side rail kit 10L and the +x\hat{ }direction for the right-side rail kit 10R. Inward movement or extension is movement or extension in an inward oriented direction, whereas outward movement or extension is movement or extension in an outward oriented direction.

As used herein, a first element may be to “couple” with a second element if the first element is capable of extending into an opening defined by the second element.

As used herein and in the appended claims, a first element is “connectable” to a second element if the first element is so configured that it is capable of being connected to the second element; however, this does not require that the first element actually be connected to the second element. For example, in the example rail kit the inner slide may not be connected to any electronic device initially, but the inner slide is nonetheless still “connectable” to an electronic device even in this state because the inner slide is so configured that it could be connected to an electronic device.

As used herein, a first element may be considered to “prevent movement” of a second element in some specified direction if the first element constrains the second element such that it cannot move in the specified direction beyond some point; however, this does not imply that the first element necessarily has to keep the second element from any and all movement in the specified direction. In other words, when it is said that some element “locks” another element, this does not mean that it completely prevents all movement of the element, but rather that it sets some constraint on movement. For example, when it is said that the first latch prevents the inner slide and middle slide from moving in both the forward direction and the rearward direction when it is in the locked position, this means that the first latch constrains the movement of the inner slide in the forward and rearward directions to be within some finite range of positions; however, the first latch does not necessarily prevent the inner slide and outer slide from all forward and rearward motion and the inner slide and middle slide may move forward and rearward freely within the finite range. This reflects the fact that some finite tolerance or “wiggle room” may be inevitable due to manufacturing variances. In addition, in certain examples some finite tolerance or “wiggle room” may be intentionally included in the design to facilitate smooth functioning of the locking mechanism.

As used herein and in the appended claims, a first element is “engagable” by a second element if the first element is so configured that it is capable of being engaged by the second element; however, this does not require that the first element actually be engaged by the second element. For example, in the example rail kit the inner slide may not be engaged by the middle slide initially, but the inner slide is nonetheless still “engagable” by the middle slide even in this state because the inner slide is so configured that it could be engaged by the middle slide.

FIG. 1A, as noted above, is a block diagram of a cable management arm 100. In another example, the first cable management arm 102 and the second cable management arm 104 may include one or more cable loops. In another example, the first cable management arm 102 and second cable management arm 104 may include apertures or mounts to allow for mounting of cable loops. In another example, the first cable management arm 102 and the second cable management arm 104 may comprise a substantially flat component with a curve at the end connecting to the connector 106. In another example, the first cable management arm 102 and the second cable management arm 104 may be comprised of plastic, metal, or any other material suitable for computing device cable retention. In another example, the first cable management arm 102 and the second cable management arm 104 may be almost as long as the width of the computing device that the cable management arm 100 is attached to.

In another example, the first cable management arm 102 and/or second cable management arm 104 may comprise two separate sections. In such examples, the two sections may meet, engage, or connect at around the midpoint of a cable management arm extension. In a further example, the back side of the first cable management arm 102 and second cable management arm 104 (in other words, the side opposite where the cable management arm extension is located) may include a channel in one section and a rail attached to the other section. The rail may insert into the channel, when the two sections are adjacent or engaged. Upon extension of the cable management arm 100, the rail may extend out of the channel. In another example, a spring may connect the rail to the other section (in other words the section with the channel) of the first cable management arm 102 and second cable management arm 104. In such examples, upon retraction of the cable management arm 100, the spring may force the rail to snap back into the channel. In other word, the spring may provide an amount of tension to assist the cable management arm extension in returning back to shape.

As noted above, the first cable management arm 102 and/or the second cable management arm 104 may include a cable management arm extension. The cable management arm extension may be U-shaped. In another example, the cable management arm extension may be composed of a flexible material. In such examples, the cable management arm extension may be one piece. For example, as the cable management arm 100 extends and the first cable management arm 102 and the second cable management arm 104 are pulled out and apart, the sections of the first cable management arm 102 and the second cable management arm 104 may separate. During such an occurrence, the cable management arm extension (whether on the first cable management arm 102 or the second cable management arm 104) may flatten, thus allowing the cable management arm 100 to travel further. In another example, the cable management arm extension may be comprised of hinged sections and plates. In such examples, the cable management arm extension may include two hinged sections each connected to a section of the first cable management arm 102 or the second cable management arm 104. The hinged sections may also connect to a plate section. The plate section may include a cable loop, apertures to allow for installation of a cable loop, or other mounting components to allow for installation of a cable loop. In an example, the cable management arm extension may allow for the cable management arm 100 to extend further than normal. For example, a computing device may include an enclosure extension, thus lengthening the computing device. To access components within the computing device, a user may extend or pull the computing device further than normal. The cable management arm 100, with at least one cable management arm extension (included in either the first cable management arm 102 or second cable management arm 104), may support such a computing device and the extra distance the computing device may extend.

In another example, the connector 106 may be a C or U shaped component. In another example, the connector 106 may pivotally connect to the first cable management arm 102 and the second cable management arm 104 via hinge, latch, pin, some other means for physically or mechanically coupling or fastening physical components, or some combination thereof. The connection between the first cable management arm 102 and the connector 106 may allow the first cable management arm 102 to move outward from the connection. Additionally, the connection between the second cable management arm 104 and the connector 106 may allow the second cable management arm 104 to move outward from the connection. In another example, the connector 106 may include a stop or protrusion to prevent the first cable management arm 102 and/or second cable management arm 104 from moving inwards, in relation to the connection between the connector 106 and the first cable management arm 102 and/or second cable management arm 104.

In another example, the connector 106 may include a flat triangular or wedge shaped section. The section may be formed on or integral to the connector 106. The section of the connector may include an aperture. A portion of the rail kit 108 corresponding to the aperture of the section may include an aperture. In a further example, the outer slide 114 may include the aperture, while the inner slide 112 may not. In other words, the connector 106 may be pinned to the outer slide 114, but not the inner slide 112. In another example, the rail kit 108 may include a short slide 202. The short slide 202 may slidably connect to the outer slide 114. In such examples, the connector 106 may pin or fasten to the short slide 202, rather than to the outer slide 114. In such examples, the outer slide 114 may not include an aperture. A pin or fastener may be inserted into the corresponding apertures and secured. In a further example, the pin or fastener may allow the connector 106 to pivot about the rail kit 108. Thus, as the cable management arm 100 extends the connector 106 may pivot about the rail kit 108, allowing the cable management arm 100 to move forward and towards the first rail kit of the computing device.

As noted above, the connector 106 may not connect directly to the outer slide 114. In such examples, the connector 106 may connect to a short slide 202. In such examples, the short slide 202 may slidably connect to the outer slide 114. In such examples, the short slide 202 may slide along the outer slide 114. In a retracted position the short slide 202 and connector 106 may be located close to one side of the rack or, in other words, near the second rail kit of the computing device. As the computing device extends or pulls forward (in other words, pulls out from a rack), the short slide 202 and connector 106 may travel up the outer slide 114. In a fully extended position, the short slide 202 and connector 106 may be located near the first rail kit of the computing device. In such examples, the outer slide 114 may include a stop at one or both ends, to prevent movement or prevent the short slide 202 from extending past the past the ends of the outer slide 114.

As noted above, additional support may be utilized for additional cabling (as in, the additional weight, amount, and/or length of cables). In addition, the cable management arm 100 may support a 1U computing device, a 2U computing device, a 4U computing device, or larger/smaller computing devices. In a further example, the 1U computing device (or any other size computing device) may be longer than a typical 1U computing device. In such examples, longer cabling may be utilized to allow for the computing device to be pulled further out of a rack, thus allowing a user access to all components internal to the computing device. The rail kit 108 for the cable management arm 100 may add additional support and stability to the cable management arm 100. The rail kit 108 may follow the cable management arm 100 as the cable management arm 100 extends. In such examples, the rail kit 108 may attach to the connector 106. As the cable management arm 100 extends, the connector 106 and rail kit 108 may move forward or outward and towards the first rail kit of the computing device. Thus the rail kit 108 may support the first cable management arm 102, the second cable management arm 104, and the connector 108.

FIG. 1B is a block diagram of a cable management arm retainer 10, according to an example. As noted above, the cable management arm retainer 110 may include an attachment bracket 118. In an example, the attachment bracket 118 may be an L-shaped or angled bracket. In another example, the attachment bracket may be angled at a 90 degree or lower angle (for example, a 75 degree angle).The attachment bracket 118, as noted above, may connect or attach to an inner slide 112 or some other cable management arm support. In another example, the attachment bracket 118 may connect to the inner slide 112 or other cable management arm support via a pin or other suitable fastener. In such examples, the pin or fastener may allow for the inner slide to pivot about the attachment bracket 118. In another example, the attachment bracket 118 may be fixedly or removably connected to the inner slide 112 or other cable management arm support.

In another example, the attachment bracket 118 may be comprised of a material of sufficient strength to support the weight or a portion of the weight of the cable management arm 100. In other words, in a retracted position or extended position, the attachment bracket 118 may support the weight at the point where the inner slide 112 connects, engages, or attaches to the attachment bracket 118 without bending or sagging. In such examples, the attachment bracket 118 may be comprised of metal.

In another example, the cable management arm retainer 110 may include a rail kit connector 120. In an example, the attachment bracket 118 may connect, engage, or attach to the rail kit connector 120. In another example, a gap may be maintained between the rail kit connector 120 and attachment bracket 118 to allow for the rail kit connector 120 to re-orient or shift about the or in relation to the attachment bracket 118. In another example, the attachment bracket 118 may connect, engage, or attach to the rail kit connector 120 via a pin or other fastener to allow movement of the rail kit connector 120. In an example, the rail kit connector 120 may include a stop or protrusion to prevent the rail kit connector 120 from moving in a certain direction (in other words, the rail kit connector 120 may move about the attachment bracket 118 in one direction) or moving too far in one direction.

In another example, the rail kit connector 120 may include a latch. In such examples, the attachment bracket 118 may include apertures. Further, the latch may include a protrusion to lock or fit into the apertures of the attachment bracket 118. Further still, the latch may be actuated (for example, to actuate the latch, a user may depress, push, or pull the latch). When the latch is actuated, the rail kit connector 120 may be allowed to move about or re-orient about the attachment bracket 118. In another example, the rail kit connector 120 may include an end to attach to a connector of a rail kit of a computing device.

FIG. 2 is a schematic view of a cable management arm 100 attached to a computing device 230. In such examples, the cable management arm 100 may attach at the rear or back of the computing device 230. In an example, the cable management arm 100 may include a first cable management arm 102 and a second cable management arm 104. The first cable management arm 102 may pivotally connect to one end of connector 106, via pin 235, while the second cable management arm 104 may pivotally connect, via pin 231, to the other end of the connector 106. In such examples, the connector 106 may include stops or protrusions 232, 233 to prevent the first cable management arm 102 and the second cable management arm 104 from moving towards each other or inwards. For example, if a user attempts to push the first cable management arm 102 towards the second cable management arm 104, protrusion 232 may prevent the first cable management arm 102 from moving further than shown in FIG. 2 towards the second cable management arm 104.

In such examples, the other end of the first cable management arm 102 may include a latch 220 to connect to or engage with a first connector 222 of a first rail kit 224 of the computing device 230. Further, the other end of the second cable management arm 104 may include a latch 218 to connect to or engage with a second connector (not visible) of the first rail kit of the computing device 230. In such examples, the second connector of the first rail kit of the computing device 230 may remain stationary (as in, not move as the computing device 230 is extended/retracted). In another example, the first cable management arm 102 and the second cable management arm 104 may attach or connect to the second rail kit 226 of the computing device 230.

In another example, the connector 106 may connect to a rail kit 108. The rail kit 108 may include an inner slide 112, an outer slide 114, and a short slide 202. The connector 106 may connect to the outer slide 114 or, if present, the short slide 202. The short slide 202 may slidably connect to the outer slide 114. The inner slide 112 may slidably connect to the outer slide 114. In other words, the inner slide 112 may fit or insert into a channel of the outer slide 114. In another example, the inner slide 112 may pivotally connect to the attachment bracket 118 of the cable management arm retainer 110. In such examples, the rail kit connector 120 of the cable management arm retainer 110 may connect to or engage with the connector 228 of the second rail kit of the computing device 230. In such examples, connector 228 of the second rail kit of the computing device 230 may remain stationary (as in, not move) as the computing device 230 is extended/retracted. In such examples, the inner slide 112 of the rail kit 108 may pivotally attach to the connector 228 of the second rail kit 226. In another example, when the first cable management arm 102 and the second cable management arm 104 attaches or connects to the second rail kit 226 of the computing device 230, the cable management arm retainer 110 may attach or connect to the first rail kit 224 of the computing device 230.

In FIG. 2, the computing device 230 and cable management arm 100 may be considered to be in a retracted, fully inserted, or installed position. In such a position, the cable management arm 100 may be closed In other words, the first cable management arm 102 may be adjacent to and/or parallel (or substantially parallel) to the second cable management arm 104.

In another example, the first cable management arm 102 may include one or more cable loops 210, 212. In an example, the first cable management arm 102 may include rigid cable loops 210 and flexible cable loops 212. In another example, the first cable management arm 102 may include a cable management arm extension 236. In such examples, the cable management arm extension 236 may include a cable loop 214 In another example, the second cable management arm 104 may include one or more cable loops 204, 206. In an example, the second cable management arm 104 may include rigid cable loops 204 and flexible cable loops 206. In another example, the second cable management arm 104 may include a cable management arm extension 234. In such examples, the cable management arm extension 236 may include a cable loop 208. In another example, the cable management arm retainer 110 may connect to the inner slide 112 via an attachment bracket (not shown). Further, the cable management arm retainer 110 may engage with or attach to the connector 228 of the second rail kit 226 via a rail kit connector 120.

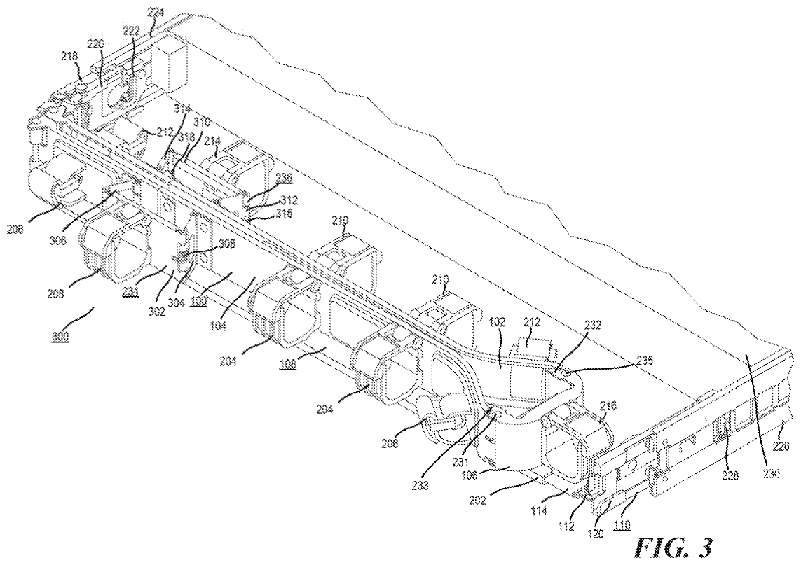

FIG. 3 is a close-up schematic view of a cable management arm 100 attached to a computing device 230. As noted above, the first cable management arm 102 may include a cable management arm extension 236. In another example, the second cable management arm 104 may include a cable management arm extension 234. The cable management arm extension 234, 236 may include a first hinge 304, 312 fixedly connected, via pin or other fastener, to one of the first or second cable management arms 102, 104. The cable management arm extension 234, 236 may include a second hinge 306, 314 fixedly connected, via pin or other fastener, to one of the first or second cable management arms 102, 104. The first hinge 304, 312 and the second hinge 306, 314 may each hingedly connect to an end of a flat piece or plate 302, 310, thus forming the cable management arm extension 234. In another example, the connection point between the first hinge 304 and plate 302 may include a spring 308 and the connection point between the second hinge 306 and plate 302 may include spring (not visible), the springs to prevent the cable management arm extension 234 from over-extending or extending inwards. In another example, the spring 308 may provide tension to allow for the cable management arm extension 234 to return to shape upon retraction from an extended position. In another example, the connection point between the first hinge 312 and plate 310 may include a spring 316 and the connection point between the second hinge 314 and plate 310 may include spring 318, the springs to prevent the cable management arm extension 236 from over-extending or extending inwards. In another example, the spring 318 may provide tension to allow for the cable management arm extension 236 to return to shape upon retraction from an extended position. In an example, the flat piece or plate 302, 310 may include apertures or mounts to allow for mounting of cable loops (for example, cable loop 208, 214).

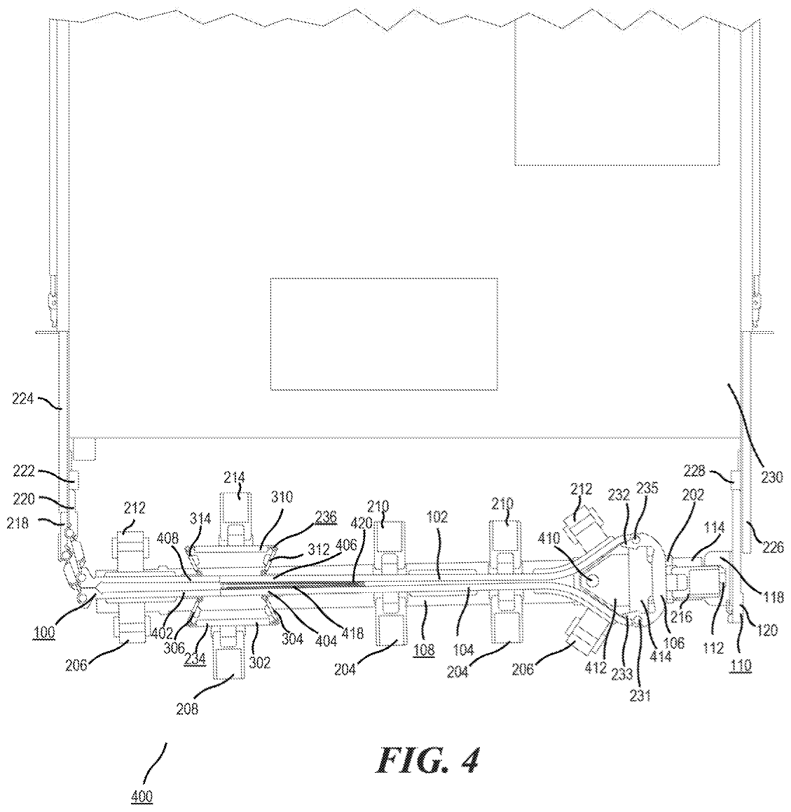

FIG. 4 is a top-down schematic view of a cable management arm 100 attached to a computing device 230. As noted above the first cable management arm 102 and/or second cable management arm 104 may comprise two separate sections. The first cable management arm 102 may include a first section 406 and a second section 408. The second cable management arm 104 may include a first section 404 and a second section 402. In such examples, the first section 404, 406 may meet, engage, or connect to the second section 402, 408 at around the midpoint of a cable management arm extension 234, 236. In an example, the back side of the first section 404, 406 may include a channel. In an example, the back side of the second section 402, 408 may include a rail. The rail may insert into the channel, when the first section 404, 406 and the second section 402, 408 are adjacent. Upon extension of the cable management arm 100, the rail may extend out of the channel. In another example, a spring 418, 420 may connect the mil to the first section 404, 406. In such examples, upon retraction of the cable management arm 100, the spring 418, 420 may force the rail to snap back into the channel. In other word, the spring 418, 420 may provide an amount of tension to assist the cable management arm extension 234, 236 in returning back to shape.

As noted above, the connector 106 may include a flat triangular or wedge shaped lower section 412 and an upper section 414. The wedge shaped lower section 412 and upper section may be formed on or integral to the connector 106. The upper section 414 may extend out from the inside of the connector 106 and include a wall that connects the upper section 414 to the wedge shaped lower section 412. The wedge shaped lower section 412 of the connector may include an aperture. A short slide 202 of the rail kit 108 may include an aperture corresponding to the aperture of the wedge shaped lower section 412. A pin 410 or fastener may be inserted into the corresponding apertures and secured. In a further example, the pin 410 or fastener may allow the connector 106 to pivot about the rail kit 108.

As noted above, the inner slide 112 may pivotally connect to the attachment bracket 118 of the cable management arm retainer 110. In such examples the cable management arm retainer 110 may include an attachment bracket 118 with an aperture or connection point formed at the bottom edge of the attachment bracket 118 (for example, where the inner slide 112 connects to the attachment bracket 118). In such examples, the inner slide 112 may pivotally connect to the attachment bracket 118 of the cable management arm retainer 110. Further, the inner slide 112 may pivotally connect to the attachment bracket 118 via a pin or fastener, which may allow the inner slide 112 to pivot about the attachment bracket 118 as the computing device 230 is extended and, thus, as the cable management arm 100 extends.

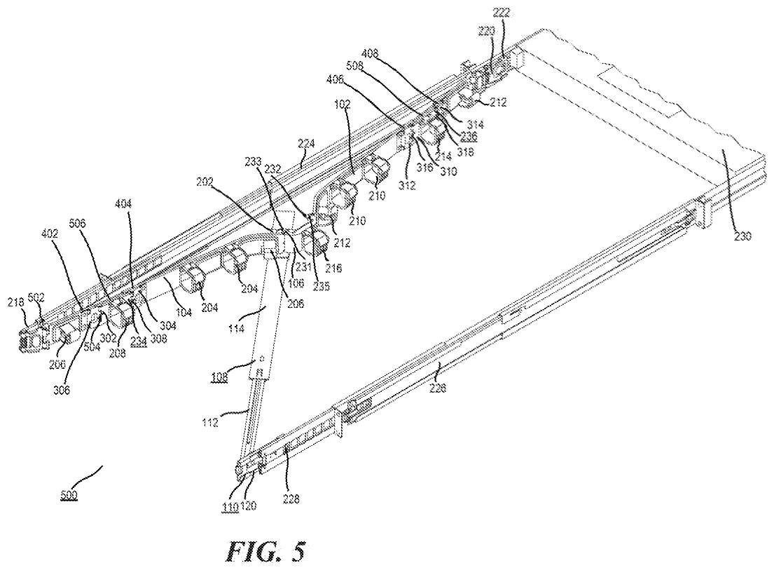

FIG. 5 is a schematic view of a cable management arm 100, in an extended position, attached to a computing device 230. In an example, the computing device 230 may be longer and heavier than a normal computing device. In such examples, the computing device 230 may extend further than normal, to allow users to reach or access various components within the computing device 230. In such examples, a standard cable management arm may not extend far enough to allow for access to every component. Additionally, merely lengthening a cable management arm may not be sufficient, as lengthening a cable management arm may prevent the cable management arm from fitting into a rack. In FIG. 5, the cable management arm 100 may be extended further than a standard cable management arm. The cable management arm 100 may extend further and fit into a rack, based on the addition of the rail kit 108 underneath the cable management arm 100, as well as the cable management arm retainer 110, supporting the additional weight and/or the addition of the cable management arm extensions 234, 236.

In another example, the other end of the second cable management arm 104 may include a latch 218 to connect to or engage with a second connector 502 of the first rail kit of the computing device 230. In such examples, the second connector 502 of the first rail kit of the computing device 230 may remain stationary (as in, not move as the computing device 230 is extended/retracted).

As noted above, the back side of the first section 404, 406 may include a channel. In an example, the back side of the second section 402, 408 may include a rail 506, 508. The rail 506, 508 may insert into the channel, when the first section 404, 406 and the second section 402, 408 are adjacent. Upon extension of the cable management arm 100, the rail 506, 508 may extend out of the channel.

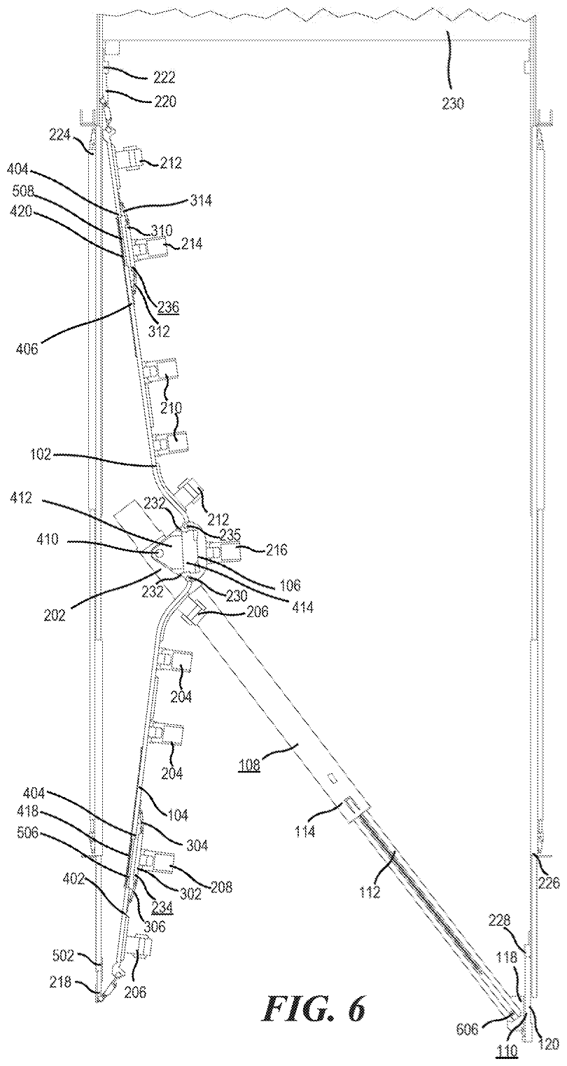

FIG. 6 is a top-down schematic view of a cable management arm 100, in an extended position, attached to a computing device 230. As noted above, the inner slide 112 may pivotally connect to the attachment bracket 118 of the cable management arm retainer 110. In such examples, the cable management arm retainer 110 may include an attachment bracket 118 with an aperture or connection point formed at the bottom edge of the attachment bracket 118 (for example, where the inner slide 112 connects to the attachment bracket 118). In such examples, the inner slide 112 may pivotally connect to the attachment bracket 118 of the cable management arm retainer 110. Further, the inner slide 112 may pivotally connect to the attachment bracket 118 via a pin 606 or fastener.

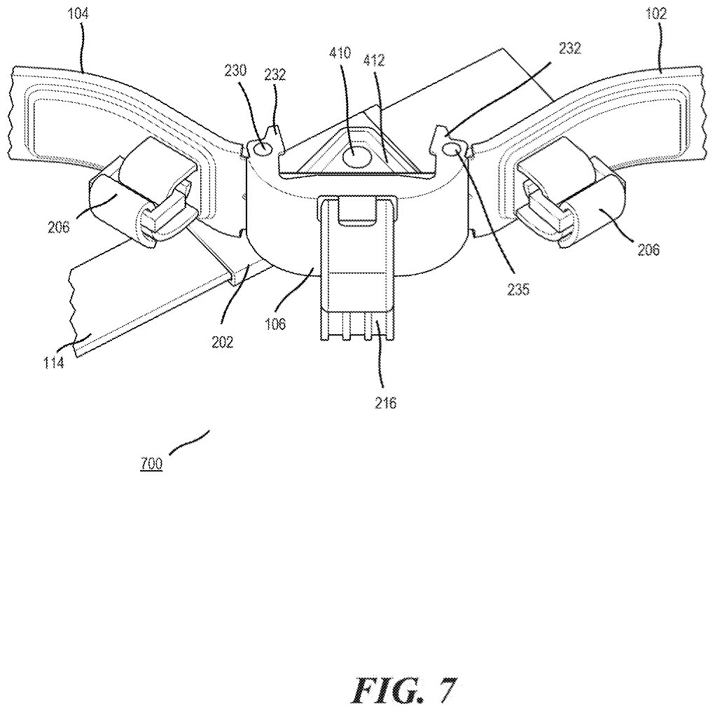

FIG. 7 is a schematic view of the connector 106. As noted above, the connector 106 may include a flat triangular or wedge shaped tower section 412 and an upper section 414. The wedge shaped lower section 412 and upper section may be formed on or integral to the connector 106. The upper section 414 may extend out from the inside of the connector 106 and include a wall that connects the upper section 414 to the wedge shaped lower section 412. The wedge shaped lower section 412 of the connector may include an aperture. A short slide 202 of the rail kit 108 may include an aperture corresponding to the aperture of the wedge shaped lower section 412. A pin 410 or fastener may be inserted into the corresponding apertures and secured. In a further example, the pin 410 or fastener may allow the connector 106 to pivot about the rail kit 108.

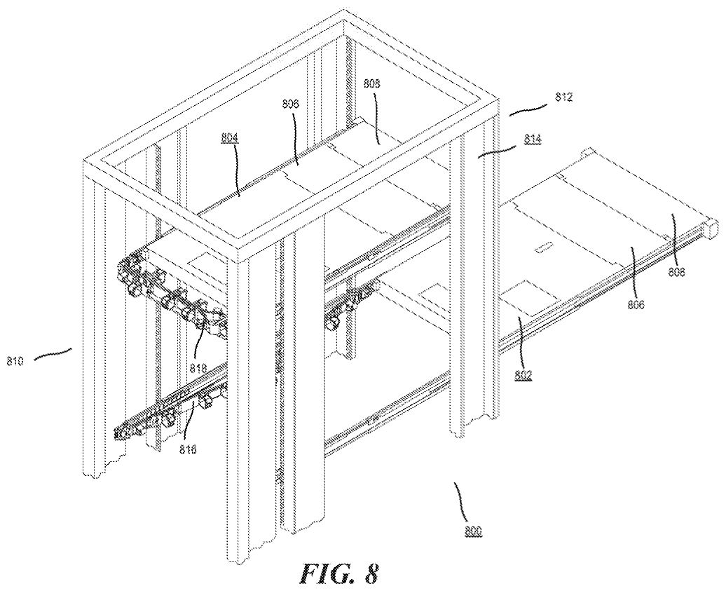

FIG. 8 is a schematic view of two computing devices 802, 804, one retracted and one extended, in a rack 814, each with a cable management arm 816, 818. In an example, the computing devices 802, 804 may be rack servers. Further, the computing devices 802, 804 may be longer and/or heavier than normal. For example, computing device 802 and computing device 804 each may include two extra device cages 806, 808 (for example, drive cages). In such examples, a user may pull the computing device, from the front 812, out further than normal to access components towards the back 810 of the computing devices 802, 804. In an example, the computing device 802, 804 may include cable management arms 816, 818, as described above. In an example, the computing device 802 is in an extended position. In another example, the computing device 804 is in a retracted or installed position.

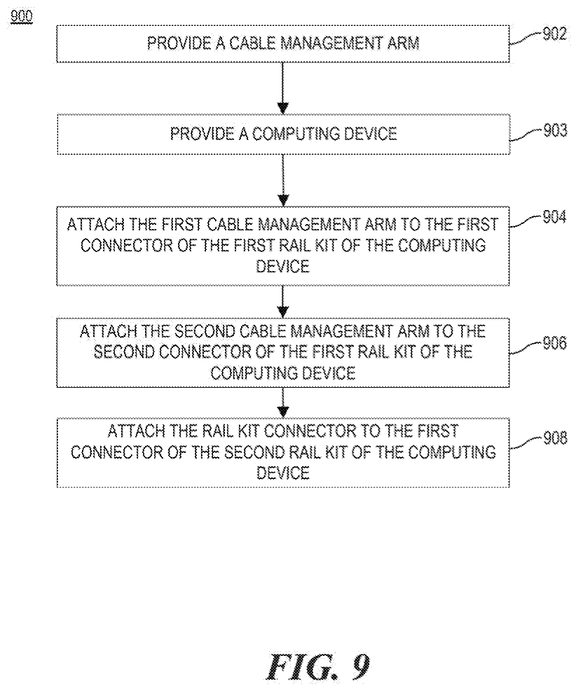

FIG. 9 is a method of attaching a cable management arm to a computing device. Although execution of method 900 is described below with reference to the cable management arm 100 and computing device 230 of FIG. 2, other suitable cable management arms and computing devices may be utilized. Additionally, implementation of method 900 is not limited to such examples. At block 902, a user may provide a cable management arm 100 for attaching to a computing device 230. At block 903, a user may provide a computing device 230 (for example, a server) to attach the cable management arm 100 to.

At block 904, the first cable management arm 102 may attach to the first connector 222 of the first rail kit 224 of the computing device 230. At block 906, the second cable management arm 104 may attach to the second connector of the first rail kit 224 of the computing device 230. At block 908, the rail kit connector 120 of the cable management arm retainer 110 may attach to a connector 228 of the second rail kit 226.

In another example, a user may attach cables to the computing device 230. In another example, the user may then pass the cables through the cable loops 210, 212 214 or cable retainers of the first cable management arm 102. The user may then pass the cables through the cable loop 216, cable loops, or cable retainers of the connector 106. The user may then pass the cables through the cable loops 204, 206, 208 or cable retainers of the second cable management arm 104.

In another example, when the cables are removed from or not present in the cable management arm 100, a user may remove or disconnect the second cable management arm 104 from the second connector of the first rail kit 224. Further, the user may remove or disconnect the first cable management arm 102 from the first connector 222 of the first rail kit 224. Further still, a user may remove or disconnect the rail kit connector 120 of the cable management arm retainer 110 from the connector 228 of the second rail kit 226.

After complete removal of the cable management arm 100, a user may attach the cable management arm 100 in a different position (for example, the reverse of the original position). In such examples, the user may unlock the attachment bracket 118 from the rail kit connector 120. To unlock the attachment bracket 118, the user may actuate the latch of the rail kit connector 120. After unlocking the attachment bracket 118 from the rail kit connector 120, the user may pivot (in other words, alter or change the orientation of) the rail kit connector 120 to another position. When the rail kit connector 120 is fully moved to the other position, the latch may lock into the attachment bracket 118.

After changing the orientation of the cable management arm retainer 110, the user may attach the second cable management arm 104 to another connector of the second rail kit 226. The user may attach the first cable management arm 102 to the connector 228 of the second rail kit 226. The user may then attach the rail kit connector 120 to the second connector of the first rail kit 224. The user may then pass the cables back through the cable management arm 100.

Although the flow diagram of FIG. 9 shows a specific order of execution, the order of execution may differ from that which is depicted. For example, the order of execution of two or more blocks or arrows may be scrambled relative to the order shown. Also, two or more blocks shown in succession may be executed concurrently or with partial concurrence. All such variations are within the scope of the present disclosure.

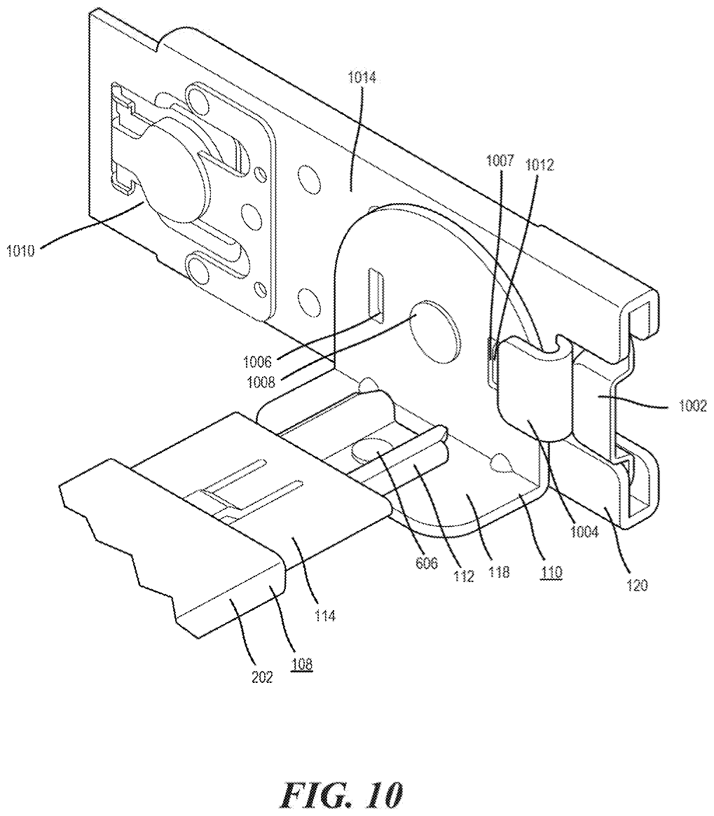

FIG. 10 is a close-up schematic view of a cable management arm retainer 110, according to an example. As noted above, the cable management arm retainer 110 may comprise an attachment bracket 118 and a rail kit connector 120. In such examples, the attachment bracket 118 may be an angled or L-shaped bracket. In another example, the bottom edge of the attachment bracket 118 may be angled upwards to allow for more support of a cable management arm in an extended position or to prevent sagging of the rail kit 108. In another example, the inner slide 112 may connect to the attachment bracket 118 via a pin 606 or fastener. In a further example, the inner slide 112 may be fixedly or removably attached to the attachment bracket 118. In another example, the attachment brackets 118 wall or side edge may connect or attach to the rail kit connector 120 or a front side or front face 1014 of the rail kit connector 120. In another example, the attachment bracket 118 may connect to the rail kit connector 120 via a pin 1008 or fastener and may be fixedly or removable connected to the rail kit connector 120. In another example, a gap may be formed between the rail kit connector 120 and the attachment bracket 118 to allow for movement, rotation, or re-orientation of the rail kit connector 120.

As noted, the rail kit connector 120 may include a latch 1002. In an example, the attachment bracket 118 may include apertures 1006, 1007 to allow for a protrusion 1012 of the latch 1002 of the rail kit connector 120 to latch onto or lock onto the attachment bracket 118. In an example, a user may actuate the latch 1002. In a further example, a user may actuate the latch 1002 by pushing or depressing the latch 1002. In such examples, the protrusion 1012, which may be included on the latch 1002, may clear the aperture 1006, 1007 (for example and as illustrated, aperture 1007) of the attachment bracket 118 (in other words, the latch 1002 may unlock from the attachment bracket 118). Further, once clear or unlocked, a user may push or pull either end of the rail kit connector 120 to re-orient the position of the rail kit connector 120 (thus, allowing the rail kit connector 120 to be reversible or fit either side of a computing device). In an example, the rail kit connector 120 may follow the edge of the attachment bracket 118. The latch 1002 may enter or lock into the other aperture 1006, 1007.

In an example, the rail kit connector 120 may include a stop 1004. The stop 1004 may prevent a user from attempting to push the rail kit connector 120 in the wrong direction or too far in one direction. In the case that a user attempts to push the rail kit connector 120 in the wrong direction or too far in one direction, the stop 1004 may hit the bottom edge of the attachment bracket 118, preventing further movement of the rail kit connector 120.

In an example, the rail kit connector 120 may include an end 1010 which may connect to a connector of a rail kit (similar to the connectors included on the first cable management arm and second cable management arms, described above).The end 1010 of the rail kit connector 120 may connect, engage, or attach connector of a rail kit.

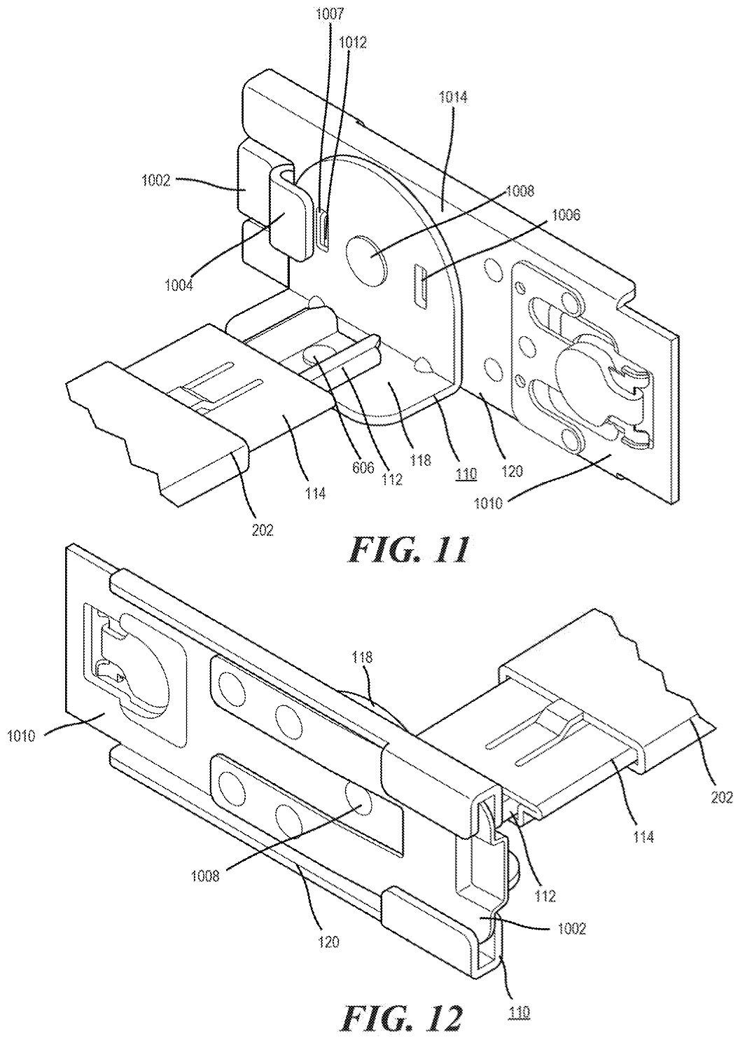

FIG. 11 is another close up view of the cable management arm retainer 110, according to an example. As noted above, the rail kit connector 120 may pivot, move, or re-orient about the attachment bracket 118. In FIG. 10, the cable management arm retainer 110 may be considered to be in a first position (for example, in an orientation allowing the cable management retainer 110 to attach to the right side of the back of a computing device). Again, as noted, a user may re-orient or pivot the rail kit connector 120 when the rail kit connector 120 is unlocked or unlatched from the attachment bracket 118. In FIG. 11, the cable management arm retainer 110 may be considered to be in a second position (for example, in an orientation allowing the cable management retainer 110 to attach to the left side of the back of a computing device).

FIG. 12 is a close-up view of the rear of the cable management arm retainer 110, according to an example. In an example, the latch 1002 may be staked or fixedly attached to the back or rear of the rail kit connector 120. In another example, the pin 1008 may be fixedly or removably attached to the rail kit connector 120. In another example, the pin 1008 may be integral or formed on the rail kit connector 120

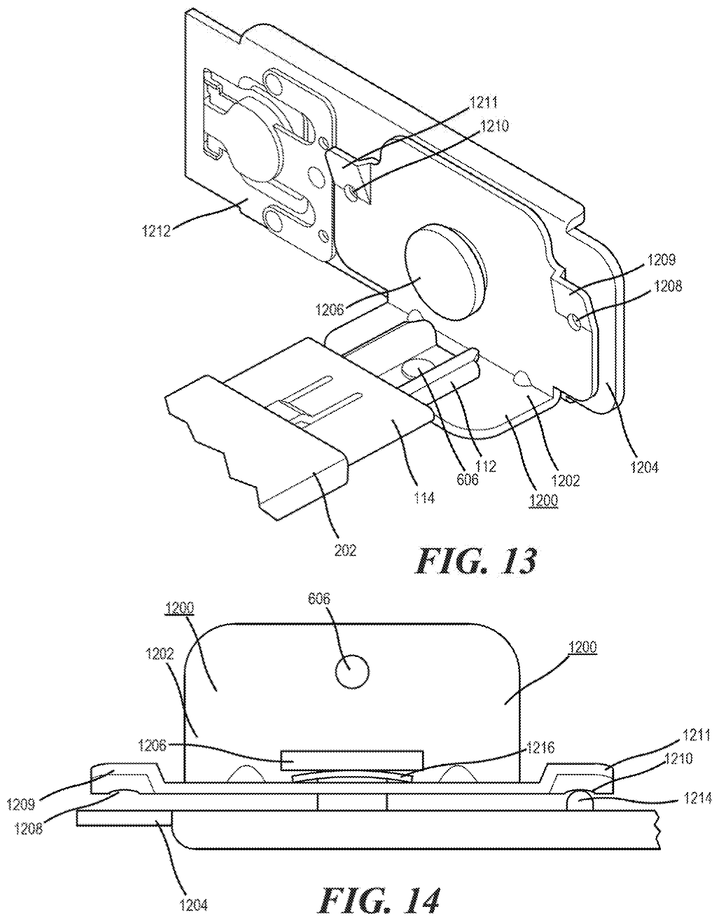

FIG. 13 is a close-up view of another cable management arm retainer 1200, according to an example. In such examples, the rail kit connector 1204 may include a protrusion (shown as 1214 in FIG. 14) to lock the attachment bracket 1202 in place. Further, the attachment bracket 1202 may include angled sections 1209, 1211 to allow for the protrusion 1214 to pass to apertures 1208, 1210 to lock the attachment bracket 1202 to the rail kit connector 1204. The angled sections 1209, 1211 may also prevent the rail kit connector 1204 from moving past the apertures 1208, 1210 (in other words, the angled sections 1209, 1211 may work as stops to prevent further movement). Further, a user may pull the rail kit connector 1204 or attachment bracket 1202 from the attachment bracket 1202 or rail kit connector 1204, respectively, to unlock the attachment bracket 1202 from the rail kit connector 1204. To lock the attachment bracket 1202 back into place, a user may press the protrusion 1214 into one of the apertures 1208, 1210 of the attachment bracket 1202.

FIG. 14 is a top-clown, close-up view of the other cable management arm retainer 1200. In another example, a washer or wavy washer 1216 may be positioned between the pin 1206 and the attachment bracket 1202. The washer or wavy washer 1216 may facilitate movement of the attachment bracket 1202 about the rail kit connector 1204.

The present disclosure has been described using non-limiting detailed descriptions of examples thereof and is not intended to limit the scope of the present disclosure. It should be understood that features and/or operations described with respect to one example may be used with other examples and that not all examples of the present disclosure have all of the features and/or operations illustrated in a particular figure or described with respect to one of the examples. Variations of examples described will occur to persons of the art. Furthermore, the terms “comprise,” “include,” “have” and their conjugates, shall mean, when used in the present disclosure and/or claims, “including but not necessarily limited to.”

It is noted that some of the above described examples may include structure, acts or details of structures and acts that may not be essential to the present disclosure and are intended to be examples. Structure and acts described herein are replaceable by equivalents, which perform the same function, even if the structure or acts are different, as known in the art. Therefore, the scope of the present disclosure is limited only by the elements and limitations as used in the claims

What is claimed is:

1. A cable management arm retainer, comprising
an attachment bracket to pivotally connect to a support of a cable management arm and to connect to a rail kit connector;
the rail kit connector including a first end, the first end to connect to first connector of a rail kit, and a second end, the second end opposite the first end and including a latch, wherein when the latch is actuated, the rail kit connector is allowed to change orientation in relation to the attachment bracket.

2. The cable management arm retainer of claim wherein the attachment bracket is pivotally connected to the rail kit connector.

3. The cable management arm retainer of claim 1, wherein the attachment bracket is comprised of metal.

4. The cable management arm retainer of claim 1, wherein the rail kit connector connects to a rail kit on a left side of a computing device or a rail kit on a right side of the computing device based on the orientation of the rail kit connector.

5. The cable management arm retainer of claim wherein when the latch is actuated, the attachment bracket is unlocked to allow for the rail kit connector to pivot about the attachment bracket.

6. The cable management arm retainer of claim 5, wherein when the rail kit connector reaches a horizontal position, the attachment bracket locks onto the latch.

7. The cable management arm retainer of claim 1, wherein the attachment bracket connects to the rail kit via a pin and a washer.

8. The cable management arm retainer of claim 7, wherein a gap is maintained between the attachment bracket and rail kit connector to allow for the rail kit connector to pivot about the attachment bracket.

9. The cable management arm retainer of claim 1, wherein a front face of the rail kit connector includes protrusions and the attachment bracket includes angled sections aligned with protrusions, the protrusions and angled sections to prevent the rail kit connector from pivoting past a first position and a second position.

10. The cable management arm retainer of claim 9, wherein when the rail kit connector is in a first position, the rail kit connector connects to a left rail kit, and when the rail kit connector is in a second position, the rail kit connector connects to a right rail kit.

11. A cable management arm, comprising
a first cable management arm to connect to a first connector of a first rail kit of a computing device and a second cable management arm to connect to a second connector of the first rail kit of the computing device;
a c-shaped connector to pivotally attach to the first cable management arm and the second cable management arm;
a rail kit, comprising:
an inner slide;
an outer slide to slidably connect to the inner slide;
a short slide to slideably connect to the outer slide and connect the c-shaped connector: and
a cable management arm retainer, comprising:
an attachment bracket to pivotally connect to an inner slide and to connect to a rail kit connector;
the rail kit connector including a first end, the first end to connect to a first connector of a second rail kit of the computing device, and a second end, the second end opposite the first end and a front face, wherein the attachment bracket is locked to the front face and, when the attachment bracket is unlocked, the rail kit connector is allowed to change orientation in relation to the attachment bracket.

12. The cable management arm of claim 11, wherein, when the orientation of the rail kit connector is changed, the rail kit connector connects to the first connector of the first rail kit of the computing device, the first cable management arm connects to a second connector of the second rail kit, and the second cable management arm connects to the first connector of the second rail kit of the computing device

13. The cable management arm of claim 11, wherein latch locks the attachment bracket in place.

14. The cable management m of claim 12, wherein, when the latch is actuated, the attachment bracket is unlocked and the rail kit connector may pivot, based on a starting position of the rail kit connector, to another orientation.

15. The cable management arm of claim 11, wherein a protrusion locks the rail kit connector in place when the protrusion is pressed into an aperture of the attachment bracket.

16. The cable management arm of claim 15, wherein, when the rail kit connector is pulled away from the attachment bracket, the protrusion is removed from the aperture and the rail kit connector is allowed to change orientation in relation to the attachment bracket.

17. A method, comprising:
providing the cable management arm of claim 11;
providing the computing device of claim 11;
inserting the computing device into a rack;
attaching the first cable management arm to the first connector of the first rail kit of the computing device;
attaching the second cable management arm to the second connector of the first rail kit of the computing device; and
attaching the rail kit connector to the first connector of the second rail kit of the computing device.

18. The method of claim 17, further comprising:
removing the first cable management arm from the first connector of the first rail kit of the computing device;
removing the second cable management arm from the second connector of the first rail kit of the computing device; and
removing the rail kit connector from the first connector of the second rail kit of the computing device

19. The method of claim 18, further comprising:
unlocking the attachment bracket from the rail kit connector; and
changing the orientation of the rail kit connector in relation.

20. The method of claim 19, further comprising:
attaching the first cable management arm to the second connector of the second rail kit of the computing device;
attaching the second cable management arm to the first connector of the second rail kit of the computing device; and
attaching the rail kit connector to the second connector of the first rail kit of the computing device.
